(19) United States
(12) Patent Application Publication
(10) Pub. No.: US 2009/0211839 A1
(43) Pub. Date: Aug. 27, 2009

(54) SPEAKER CABINET AND SPEAKER ATTENUATION SYSTEM, METHOD, AND APPARATUS

(76) Inventor: Frank LaMarra, West Bloomfield, MI (US)

Correspondence Address: HARNESS, DICKEY & PIERCE, P.L.C., P.O. BOX 828, BLOOMFIELD HILLS, MI, 48303, US

(21) Appl. No.: 12/355,120

(22) Filed: Jan. 16, 2009

Related U.S. Application Data
(63) Continuation-in-part of application No. 11/867,285, filed on Oct. 4, 2007.
Application No. 11/867,285 is a continuation-in-part of application No. 11/332,882, filed on Jan. 13, 2006.

(51) Int. Cl. H05K 5/00; G10K 11/18

(52) U.S. Cl. 181/151; 181/155

(57) ABSTRACT

A speaker attenuation system includes a foam attenuating member attached to a mounting bracket. The mounting bracket is configured for attachment to a baffle board of a speaker cabinet and the foam attenuating member is configured to be positioned in a central beam region of a speaker of the speaker cabinet when the mounting bracket is attached to the baffle board.

### CROSS-REFERENCE TO RELATED APPLICATIONS

This application is a continuation-in-part of U.S. patent application Ser. No. 11/867,285, filed on Oct. 4, 2007, which is a continuation-in-part of U.S. patent application Ser. No. 11/332,882 filed on Jan. 13, 2006. The disclosure of the above application is incorporated herein by reference in its entirety for any purpose.

### FIELD

The present disclosure generally relates to speakers and speaker cabinets for use with musical instruments, and relates in particular to attenuation of a speaker in a speaker cabinet.

### BACKGROUND

The statements in this section merely provide background information related to the present disclosure and may not constitute prior art.

Speakers and speaker cabinets, and guitar speaker cabinets in particular, have long suffered from a tendency to project frequencies unevenly to an audience, such as performers, listeners, and microphones positioned in front of the speakers. With reference to FIG. 3A, a typical speaker mounted in a speaker cabinet, tends to project sound in a beam in front of the speaker cabinet. This beam has a central beam region 100, and outer beam regions 100A and 100B. In general, the higher frequencies, such as frequencies above one-thousand Hertz, present in the central beam region 100 are significantly greater in amplitude than the lower frequencies, such as those below one-thousand Hertz, present in that region. Conversely, the higher frequencies present in the outer beam regions 100A and 100B tend to be of lesser amplitude than the higher frequencies present in the central beam region 100. These higher frequencies present in the outer beam regions 100A and 100B also tend to more closely match the lower frequencies present in the outer beam regions 100A and 100B. As a result, the outer beam regions 100A and 100B are generally perceived by musicians, recording professionals, and others as having a more even tone than the central beam region 100.

Turning now to FIG. 5, a response curve 500 produced by placing the microphone close to the cabinet of FIG. 3A in the central beam region demonstrates the increased amplitude of higher frequencies in the central beam region. As a general rule, the higher the frequency, the more narrow the “beam” of that frequency that tends to be projected forward from the voice coil in the center of the speaker. This voice coil vibrates during operation, causing a conical membrane of the speaker that is attached to the voice coil to similarly vibrate. In contrast to the higher frequencies, lower frequencies tend to project forward from the entire conical membrane and disperse evenly in front of the speaker.

While response curve 500 extends from five-hundred Hertz to eight-thousand Hertz, it should be readily apparent to one skilled in the art that the range of human hearing extends from about twenty Hertz to about twenty-thousand Hertz. It should also be readily apparent that musical instruments, such as guitars, are typically only capable of playing notes in a range from about forty Hertz, in the case of a contra base guitar, to about one-thousand seven-hundred sixty Hertz, in the case of an alto guitar. However, musical instruments, and especially electric guitars, can produce higher frequencies as harmonic overtones, especially in the case of tube amp distortion for an electric guitar or use of artificial aural excitation for an electric/acoustic guitar. These harmonic overtones can easily range up to eight-thousand hertz. Thus, the presence of higher frequencies dramatically affects the tone of an amplified guitar signal.

Moreover, one skilled in the art will readily recognize that decibels are a logarithmic measure, and that perceived loudness of a sound is generally known to double with an increase of ten decibels. This perceived loudness does not directly relate to actual intensity or amplitude, which doubles with an increase of three decibels. Moreover, perceived loudness, which is an experimentally obtained psychoacoustic measure typically expressed in phons, does not directly correspond to decibels. Typically, a contouring filter, such as an A filter generally accepted for use in musical applications, can be applied to a rough conversion of decibels to phons, with the units expressed as dBA, dBB, or dBC, depending on the filter employed. Alternatively, a conversion table available in acoustics textbooks can be employed to achieve a more accurate conversion expressible as phons. However, the difference between decibels and phons or dBA is mostly significant for frequencies below one thousand Hertz and above eight thousand Hertz. For example, one skilled in the art will readily recognize that application of an A filter to curve 500 would leave points of the curve the same at one-thousand Hertz and five-thousand Hertz, while adjusting other frequencies between one-thousand and eight thousand Hertz by no more than about two decibels. Such application would, however, significantly reflect a decrease in the perceived loudness of lower frequencies below one-thousand Hertz. Accordingly, the difference between perceived loudness of the higher and lower frequencies is even more dramatic than might be otherwise reflected by curve 500.

The increased amplitude of the higher frequencies in the central beam region is generally referred to as “beaminess,” and has long been known to be an undesirable characteristic of speakers, and especially of guitar speaker cabinets, that causes various undesirable results. For example, audience members closer to the stage and positioned to receive the central beam experience “ice pick highs” or “sizzle” generally perceived as unpleasant. Also, recording professionals in the past have discovered that positioning a recording microphone in the central beam region produces undesirable results, and have learned to position the microphone in one of the outer beam regions. Similarly, live sound technicians, especially at larger venues, also need to mic one or more speakers of a guitar speaker cabinet for sound reinforcement through local PA systems. However, more often than not, these live sound technicians tend to place the microphone in the central beam region. As a result, the sound emanating from the PA system tends to be unbalanced, and the entire audience experiences the unpleasant “ice pick highs” or “sizzle.”

Turning now to FIG. 3B, attempts to reduce “beaminess” of a speaker cabinet have generally involved blocking the sound emanating from the central beam region 100. For example, others have tried placing a blocking member 106 composed of duct tape, felt, metal, fiber, and/or wood between the speaker and the audience in the central beam region 100. Typically, the blocking member 106 has been mounted inside the screen of the cabinet by attaching the blocking member 106 to the inside surface of the screen, or by providing one or more spokes extending from the cabinet baffle board on which the speaker is mounted, and attaching it to the spoke or spokes. Specifically, duct tape and/or felt discs have been attached to the screen, while wooden discs or metal and fiber discs have been mounted on spokes. Typically, the discs have been four to six inches in diameter for ten to twelve inch speakers, and slightly larger for fifteen inch speakers.

Returning now to FIG. 5, a response curve 502 produced by placing the microphone close to the blocked cabinet of FIG. 3B in the central beam region demonstrates the decreased amplitude of higher frequencies in the central beam region. Specifically, response curve 502 demonstrates the decreased amplitude of higher frequencies in the central beam region when a square section cut from a 2×4 wooden board made of pine is used as the blocking member 106. Low peaks 504A-504D in response curve 502 demonstrate that a perceptible “hole in the sound” exists for several of the higher frequencies in the central beam region when blocking is used. Blocking is known to be effective in reducing the “ice pick highs” received directly from the cabinet by audience members positioned in the central beam region. However, the “hole in the sound” is experienced by the audience in the central beam region. This “hole in the sound” is also experienced by the rest of the audience when live sound technicians inevitably place the microphone in the central beam region. As a result, most or all of the audience at a large venue experiences an unpleasantly “muddy” tone from the speaker being piped through the PA system of the venue.

Accordingly, the need remains for a way to reduce the unevenness, or “beaminess,” of a speaker without creating a perceptible “hole in the sound” in the central beam region. The present teachings address this need.

### SUMMARY

A speaker attenuation system may include a foam attenuating member attached to a mounting bracket. The mounting bracket may be configured for attachment to a baffle board of a speaker cabinet. The foam attenuating member may be configured to be positioned in a central beam region of a speaker of the speaker cabinet when the mounting bracket is attached to the baffle board.

A speaker cabinet may include a baffle board and a speaker attached to the baffle board. A foam attenuating member may be attached to a mounting bracket. The mounting bracket may be attached to the baffle board and the foam attenuating member may be positioned in a central beam region of the speaker.

A speaker attenuation method may comprise mounting a bracket to a baffle board of a speaker cabinet, the bracket having a foam attenuating member attached thereto. The foam attenuating member may be positioned in a central beam region of the speaker when the bracket is mounted to the baffle board.

Further areas of applicability will become apparent from the description provided herein. It should be understood that the description and specific examples are intended for purposes of illustration only and are not intended to limit the scope of the present disclosure.

### DRAWINGS

The drawings described herein are for illustration purposes only and are not intended to limit the scope of the present disclosure in any way.

FIG. 1 is a perspective view of an attenuated speaker cabinet in accordance with the present teachings.

FIGS. 2A and 2B are cross-sectional side views of the attenuated speaker cabinet of FIG. 1 in open and closed positions.

FIG. 3A is a cross-sectional side view of a speaker cabinet in accordance with the prior art.

FIG. 3B is a cross-sectional side view of a blocked speaker cabinet in accordance with the prior art.

FIG. 4 is a cross-sectional side view of an attenuated speaker cabinet in accordance with the present teachings.

FIG. 5 is a two-dimensional, logarithmic scale graph of speaker response curves generated with a microphone positioned in a central beam region of a speaker cabinet, wherein the abscissa denotes frequency in Hertz and the ordinate denotes amplitude in decibels metering AC rms voltage, wherein the reference voltage is one volt rms.

FIG. 6A is a perspective, blow up view of a speaker attenuation apparatus in accordance with the present teachings.

FIG. 6B is a perspective view of the speaker attenuation apparatus of FIG. 6A implemented to attenuate a 4×12 guitar speaker cabinet.

FIG. 7A is a perspective view of a guitar speaker having a tapped central housing within a center of the voice coil.

FIG. 7B is a perspective view of a guitar speaker of FIG. 7A in which a threaded member is mounted within the tapped central housing.

FIG. 7C is a perspective view of the guitar speaker of FIGS. 7A and 7B in which a disc of open cell foam is attached to the threaded member so as to be positioned within a central beam region of the speaker.

FIG. 7D is a frontal perspective view of the speaker of FIG. 7C.

FIG. 8A is a block diagram illustrating the guitar speaker of FIGS. 7C and 7D.

FIG. 8B is a block diagram illustrating the guitar speaker of FIG. 8A mounted in a guitar speaker cabinet.

FIG. 9A is a block diagram illustrating an alternative embodiment of the guitar speaker of FIG. 8A in which the threaded member is open on an anterior end to accommodate customization of the open cell foam size, thickness, and position by an end user.

FIG. 9B is a block diagram illustrating the guitar speaker of FIG. 9A mounted in a guitar speaker cabinet.

FIG. 10 is a front view of a speaker attenuation apparatus.

FIG. 11 is a back view of a speaker attenuation apparatus.

FIG. 12 is a perspective view of the speaker attenuation apparatus of FIGS. 10 and 11 implemented to attenuate a speaker in speaker cabinet.

FIG. 13 is an exploded view of the speaker, speaker attenuation apparatus, and a portion of a baffle board of the speaker cabinet of FIGS. 10 and 11.

FIG. 14 is a perspective view of the assembled speaker, speaker attenuation apparatus, and the portion of the baffle board of FIG. 13.

### DETAILED DESCRIPTION

The following description is merely exemplary in nature and is not intended to limit the present disclosure, application, or uses.

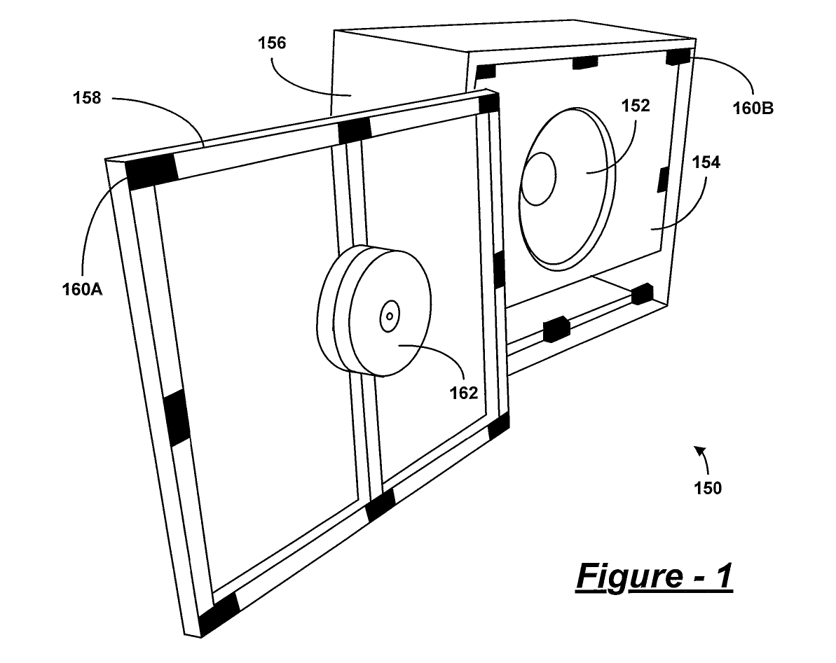

Turning now to FIG. 1, a guitar speaker cabinet 150 has a guitar speaker 152, such as a twelve inch guitar speaker, mounted on a baffle board 154 affixed within a housing 156 composed of wood and vinyl. A screen 158 is positioned in a front side of the housing 156 to protect the speaker 152. The screen 158 is removable. Fasteners, 160A and 160B, such as Velcro patches, can be used to hold a removable screen in place when it is attached to the housing 156, yet allow easy removal of the screen 158. It should be readily understood that when Velcro patches are employed as fasteners 160A and 160B, a ring patch is mated to a hook patch in order to effect fastening. Other useful fastening mechanisms will be readily apparent to those skilled in the art.

In accordance with the present teachings, an attenuating member 162 is positioned predominantly in the central beam region of the guitar speaker 152 when the speaker cabinet 150 is being operated to produce sound in a performance setting. Preferably, the attenuating member is positioned proximate to the speaker in the performance, such as within two or three feet of the speaker. For example, the attenuating member 162 can be attached to one or more portions of the guitar speaker cabinet in such a manner that it is properly positioned when the cabinet is assembled for operation. In a presently preferred embodiment, the attenuating member 162 is disc-shaped and centered in front of the voice coil of the speaker 152. The attenuating member 162 also preferably includes one or more layers of open cell foam, also known as acoustic foam, although closed cell foam may also be used. A layer can be one inch thick. A layer can also be six inches in diameter, especially for a twelve inch guitar speaker. Thus, two or more layers can be combined to form the attenuating member 162 when the speaker 152 is relatively new and therefore more “beamy.” Then, as the speaker 152 ages and becomes less and less “beamy,” layers can be progressively removed to effect less and less attenuation of the higher frequencies in the central beam region.

The attenuating member 162 can, for example, be attached to an interior of the screen 158 in any suitable manner. The attachment of the attenuating member 162 can be accomplished using a bolt assembly through a center of the attenuating member 162 that is received in a wooden strut of the screen 158. When layers are removed, a shorter bolt can be used. It should be readily understood that the attenuating member 162 can alternatively or additionally be mounted to the exterior of the screen 158, to the baffle board 154, the housing 156, and/or to the speaker 152. Moreover, any number of attachment mechanisms, such as nails, rivets, screws, staples, glue, gum, thread, latches, straps, etc. can be employed. This list of potential attachment mechanisms is not meant to be limiting in any way. Further, the attenuating member 162 does not have to be attached to the cabinet 150 or any of its components, but can be positioned in the central beam region in any manner.

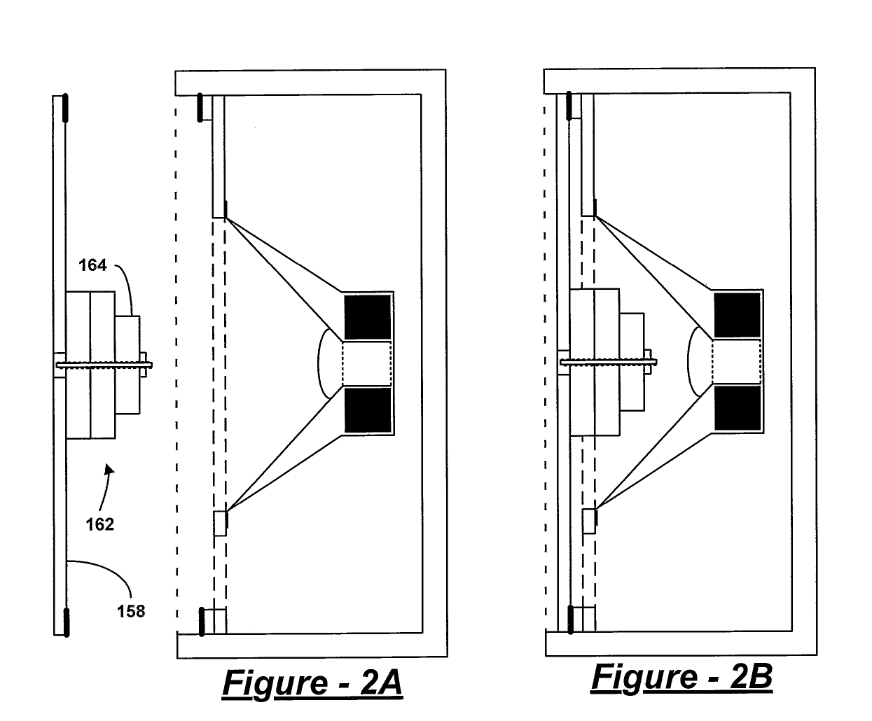

Turning now to FIGS. 2A and 2B, proper attachment of the attenuating member 162 to an interior of the screen 158 allows the attenuating member 162 to be positioned proximate to the speaker 152 within the central beam region and also out of sight of the audience when the screen 158 is attached to the housing 156. A third disc layer 164 can be added when the speaker 152 is relatively new to affect more attenuation. Care can be taken to reduce diameter of the third disc layer 164 in order to ensure that the third disc layer 164 does not contact a surface of the speaker 152 when the speaker 152 is in operation. With a twelve inch guitar speaker, a four inch disc of one inch thick open cell foam centered with respect to other disc layers of the attenuating member 162 has been found to work well as a third disc layer. Accordingly, layers of the attenuating member 162 can be of different sizes. It should also be readily appreciated that there can be any number of layers of varying shapes and thicknesses.

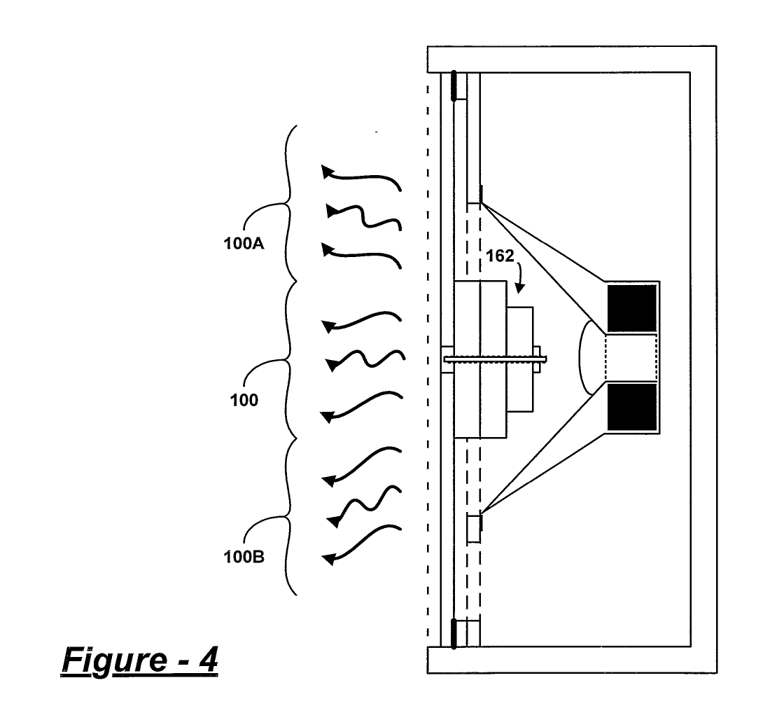

Turning now to FIG. 4, use of attenuating member 162 improves evenness of the speaker tone in a manner and to a degree that is readily perceptible to a listening guitar tone aficionado. In particular, the amplitude of higher frequencies in the central beam region 100 is reduced without creating a “hole in the sound.” Overall, the higher frequency amplitudes are caused to more closely match the amplitudes of the lower frequencies in the central beam region 100. Moreover, the amplitudes of the lower frequencies in the central beam region 100 are not adversely affected. Accordingly, the amplitudes of higher frequencies in the central beam region 100 are made more similar to those of higher frequencies in the outer beam regions 100A and 100B without causing a dramatic mismatch in amplitudes of lower frequencies in the central and outer beam regions. In other words, the “beaminess” of the speaker 152 is effectively reduced without creating a “hole in the sound” in the central beam region 100.

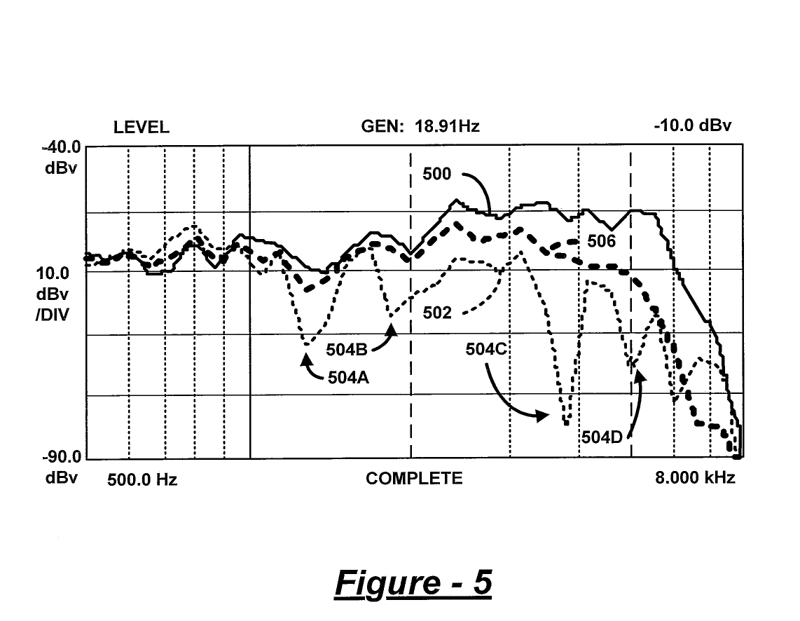

Returning now to FIG. 5, response curve 506 produced by placing the microphone close to the attenuated cabinet of FIG. 1 in the central beam region demonstrates the decreased amplitude of higher frequencies in the central beam region without creating a “hole in the sound”. Response curve 506 was produced using two one-inch thick discs of six inch diameter acoustic foam mounted centered in front of the voice coil of the speaker. The particular open cell foam (Product No. CFR-16070) was manufactured by Flexible Foam Products, Inc.™, located in Spencerville, Ohio. It was centered in front of a Celestion™ Classic Lead 80™ speaker by mounting it to the interior screen of a ported 1×12 Egnater™ speaker cabinet available from Music Products Group™ located in Oak Park, Mich. Compared to response curve 502, curve 506 clearly lacks low peaks like peaks 504A-504D of curve 506. Moreover, amplitudes of higher frequencies of curve 506 more closely match amplitudes of lower frequencies of curve 506, especially compared to curves 500 and 502. Thus, reduction of “beaminess” without creating a perceptible “hole in the sound” is effectively demonstrated. Finally, each of curves 500 and 506 were found to be significantly identical in the range of zero Hertz to five-hundred Hertz. Accordingly, the attenuating member does not adversely affect the amplitude of these lower frequencies.

It should be noted that open cell foam, while presently preferred as a material for the attenuating member 162 and disc layer 164, may be replaced with a future equivalent when it is discovered to have properties suitable for use as an attenuating member. Further, closed cell foam may be used in place of open cell foam. Further, other shapes, sizes, and varieties of acoustic foam are available and may reveal different attenuation characteristics. In general, suitable properties for material used to form the attenuating member 162 include the ability, at some uniform or non-uniform thickness, to reduce amplitude of a majority of frequencies between one-thousand and eight-thousand Hertz by at least six decibels without reducing amplitude of any frequencies in that range by more than eighteen decibels. It should be readily understood that the material need not be employed at a thickness to accomplish at least six decibels of attenuation for the majority of frequencies in the range. Rather, it is sufficient that the material be capable of so attenuating the frequencies at some thickness. More preferably, suitable properties for material used to form the attenuating member include the ability, at some uniform or non-uniform thickness, to reduce amplitude of a majority of frequencies between one-thousand and eight-thousand Hertz by at least eight decibels without reducing amplitude of any frequencies in that range by more than sixteen decibels. Moreover, it is envisioned that layers of different materials having different properties that are suitable when layered can be combined to form the attenuating member 162. In this case, the combination of materials has the suitable properties. One skilled in the art is reminded that the layers can be of different thicknesses, shapes, and sizes.

Various embodiments are possible according to suitable properties of material for forming the attenuating member. For example, in some embodiments, suitable properties will allow the material to reduce amplitudes of all frequencies between two and five thousand Hertz by at least four decibels without succeeding in reducing amplitudes of any of those frequencies by more than twelve decibels. In another additional or alternative embodiment, suitable properties will allow the material to reduce amplitudes of a majority of frequencies between two thousand and five thousand Hertz by at least four decibels without reducing amplitudes of any frequencies between one and five thousand Hertz by more than twelve decibels.

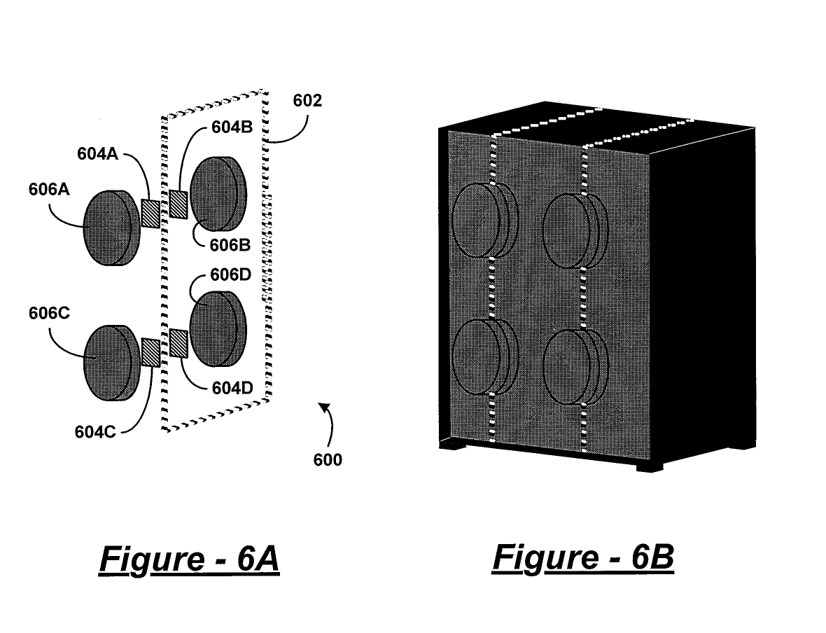

Turning now to FIG. 6A, a speaker attenuation apparatus 600 according to the present teachings includes an attenuating member. It also includes a positioning mechanism operable to position the attenuating member predominantly in the central beam region of a speaker when the speaker is being operated to produce sound in a performance setting. The positioning mechanism can be an attachment mechanism that is operable to attach the attenuating member to a speaker cabinet. For example, a strap 602 and sticky and/or Velcro patches 604A-604D can be provided in order to attach discs 606A-606D of acoustic foam to an exterior of a guitar cabinet. The discs 606A-606D can be colored or covered with material that causes them to have an appearance similar to a screen of a speaker cabinet. The strap 602 can be made of Velcro and/or elastic, can be light transmissive, and can be of sufficient length to vertically encircle one or more models of guitar cabinets. The patches 604A-604D can be attached by their sticky backs to the discs 606A-606D and mated to opposite surfaces of strap 602 so as to be hidden from sight when the apparatus 600 is assembled.

Turning now to FIG. 6B, one or more assembled apparatuses can be implemented to attenuate cabinets having multiple speakers, such as a 4×12 guitar cabinet. It should be readily appreciated that 1×12 cabinets will require that only one speaker be attenuated, while 2×12 cabinets and 4×12cabinets can be provided with an attenuating member for one or more speakers. Running the strap vertically instead of horizontally facilitates effective positioning of the attenuating members with slanted cabinets. A clear strap and screen-colored discs assist in hiding the apparatus from the audience when applied externally. However, it is envisioned that some manufacturers and/or performers may choose to decorate or modify the appearance of the apparatus. For example, the attachment mechanism can appear as a chain and the attenuating members as skulls or pocket watches. Alternatively, the attachment mechanism can appear as a vine, and the attenuating members as flower blossoms. Other possible motifs and similar variation in equipment will be readily apparent to those skilled in the art, such as ropes and nets with fish, eyeballs, sports equipment, and others.

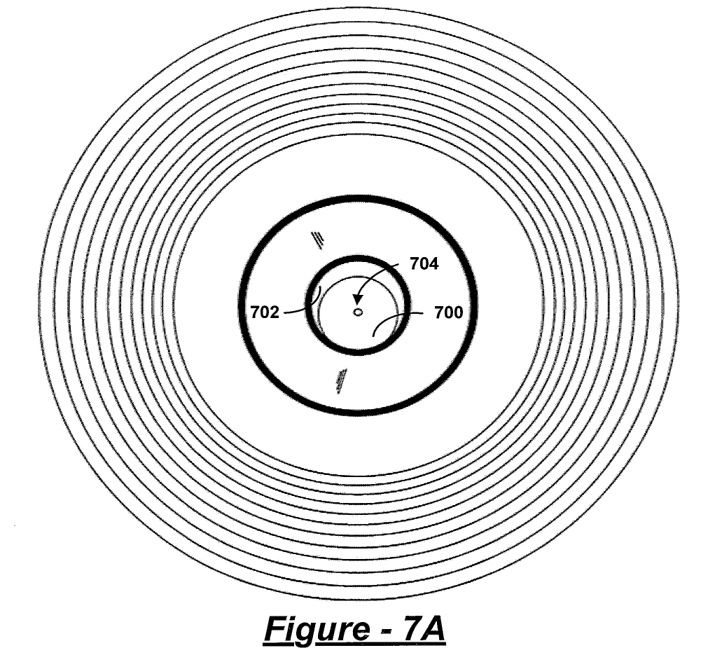

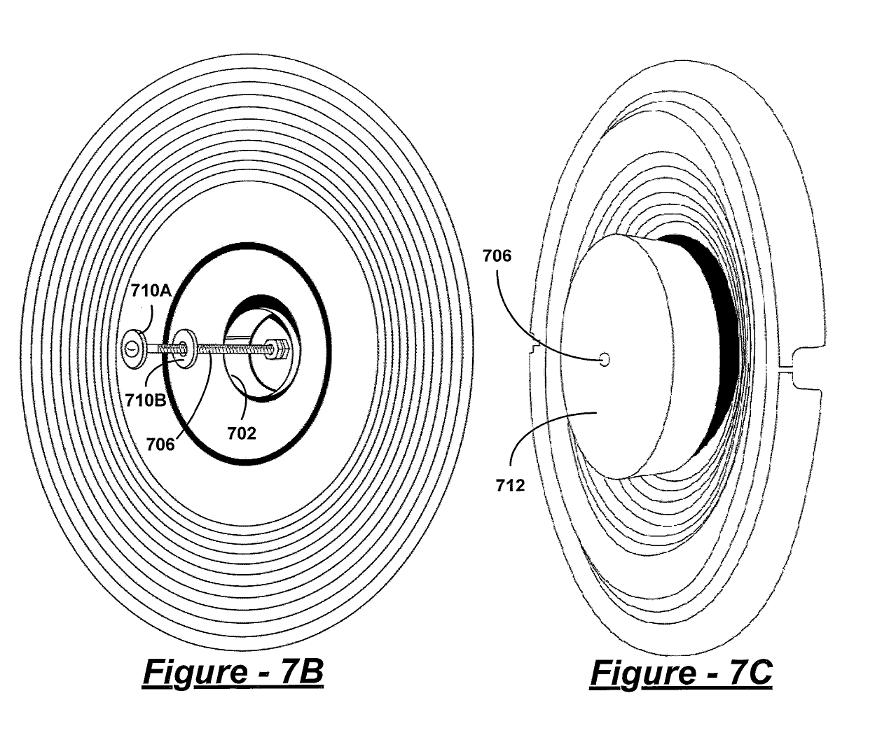

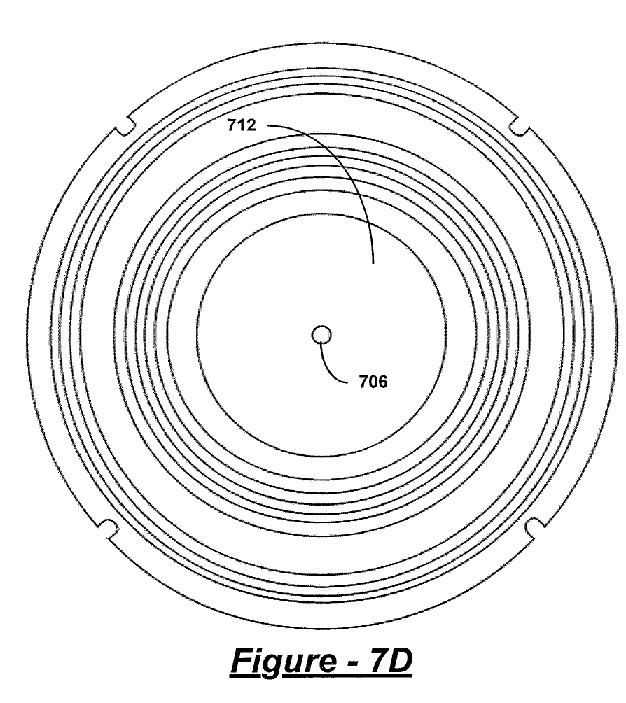

Turning now to FIGS. 7A-D, one or more layers of open cell foam or other suitable material can be attached to the speaker in some embodiments. Referring particularly to FIG. 7A, one way to attach the open cell foam or other suitable material to the speaker is to tap a central housing 700 of the speaker within a center of the voice coil 702 to form a threaded hole 704. This central housing 700 provides an inner wall for a circular groove into which the voice coil 702 moveably fits. The central housing 700 is typically made of solid metal and is not a moving part of the speaker.

Referring now to FIG. 7B, a threaded member 706, such as a bolt, can be screwed into place within the threaded hole so that it extends forward in front of the speaker. The threaded member 706 can be made of any material. In a presently preferred embodiment, the threaded member 706 is made of non-ferrous material so as not to be affected by nor interfere with operation of the speaker electromagnet that drives motion of the voice coil 702. It is envisioned that the threaded member 706 can be made of aluminum or nylon. It should also be readily understood that the threaded member 706 is but one example of an elongated member that can be affixed to the central housing 700 and employed to position the open cell foam in the central beam region in front of the voice coil. For example, a non-threaded member can be welded or glued to the central housing 700 and the open cell foam can be glued or positioned with springs, clips, or other devices to the non-threaded member.

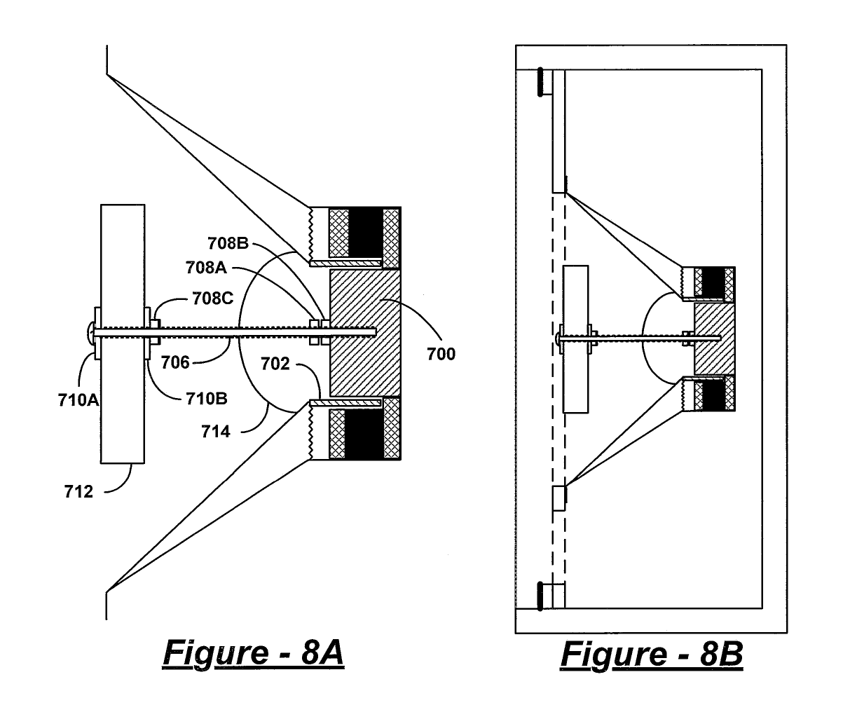

Referring now generally to FIGS. 7B-7D as well as FIGS. 8A and 8B, the threaded member 706 can be fixed in the threaded hole formed by tapping the central housing using one or more commercially available products such as Loctite™ Threadlocker™. Positioning of the threaded member 706 within the threaded hole can in part be determined by employing one or more hex nuts 708A and 708B to control a depth to which the threaded member 706 can be screwed into the threaded hole formed in the central housing 700. Material layer positioning devices, such as an additional hex nut 708C and washers 710A and 710B, can be positioned on the threaded member 706 to hold one or more layers 712 of open cell foam or other suitable material in place in front of the speaker in the beam region. It is envisioned that the hex nuts 708A and 708B, and the material layer positioning devices can be made of the same material as the threaded member, or of different material. It should be readily understood that a dust cover 714 can be perforated and attached to the speaker with the threaded member extending through the perforation in the dust cover 714.

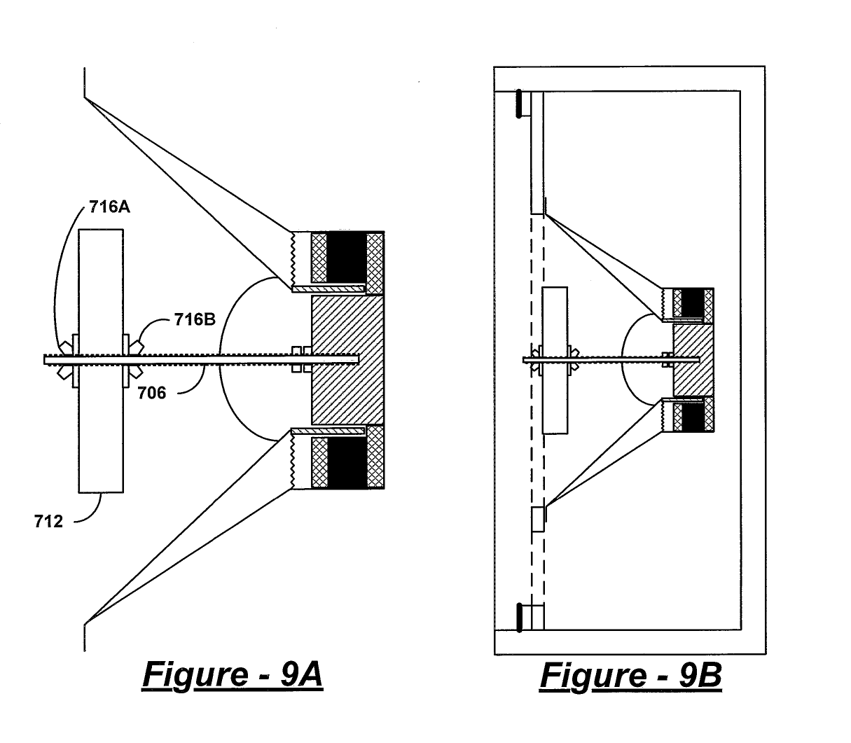

Turning now to FIGS. 9A and 9B and referring generally thereto, it should be readily understood that the threaded member 706 in some embodiments can be open on an anterior end. Similarly, one or more wing nuts 716A and 716B can be employed to control positioning of the material layers 712. In this case, the end user is able to quickly and easily customize attenuating material size, thickness, and position.

As taught herein, the speaker attenuation method, system, and apparatus is capable of improving evenness of tone of a speaker by reducing “beaminess” of the speaker without creating a “hole in the sound.” As a result, audiences in large venues will be treated to a pleasing tone even when the sound technician places the microphone to the local PA system in the central beam region of the speaker. Moreover, audience members proximate to the speaker in the central beam region will also experience the pleasing tone, and not the “ice pick highs” or “sizzle” of an unattenuated speaker, or the “muddy” tone of a blocked speaker.

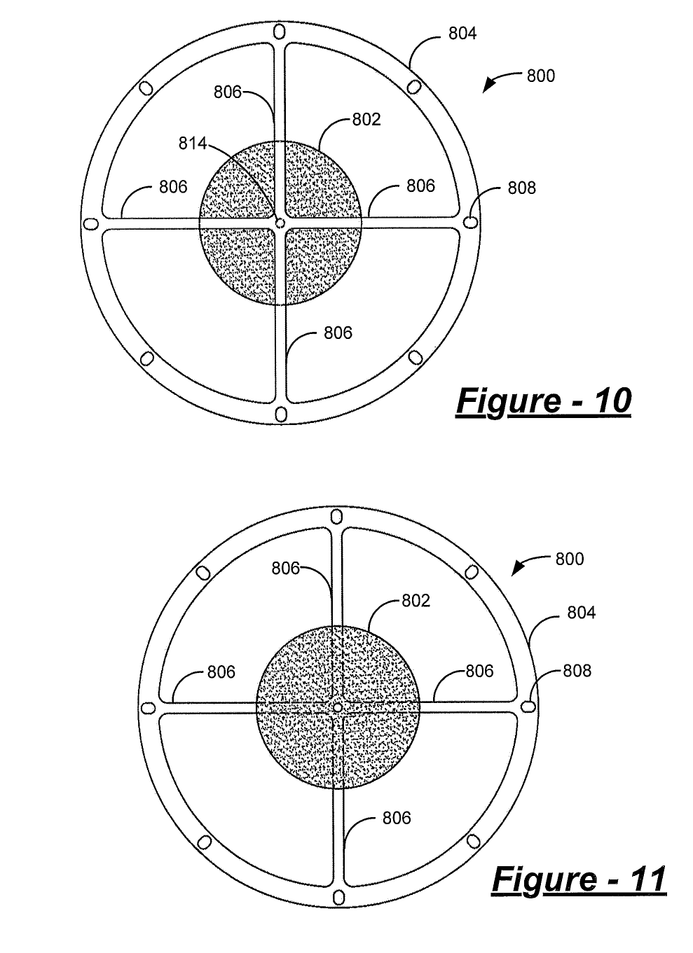

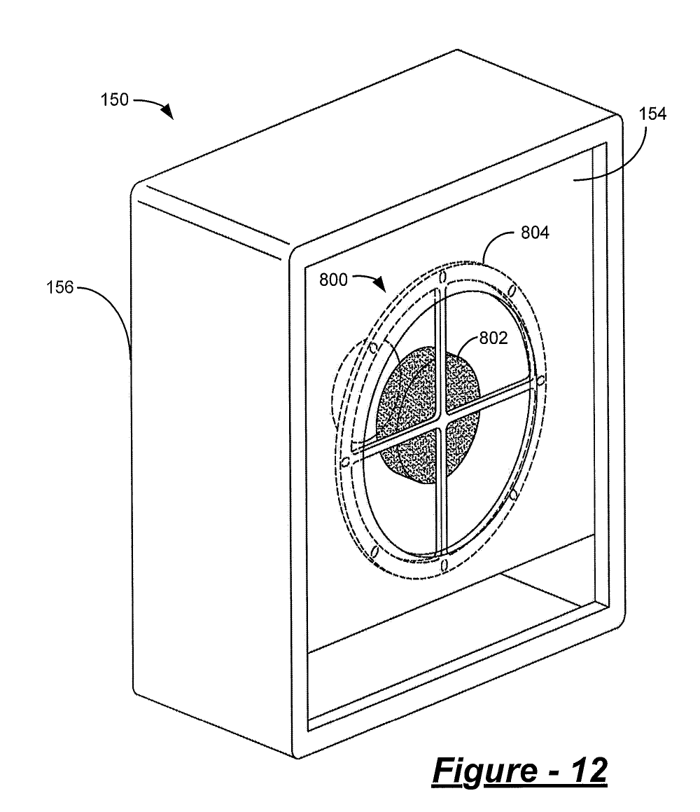

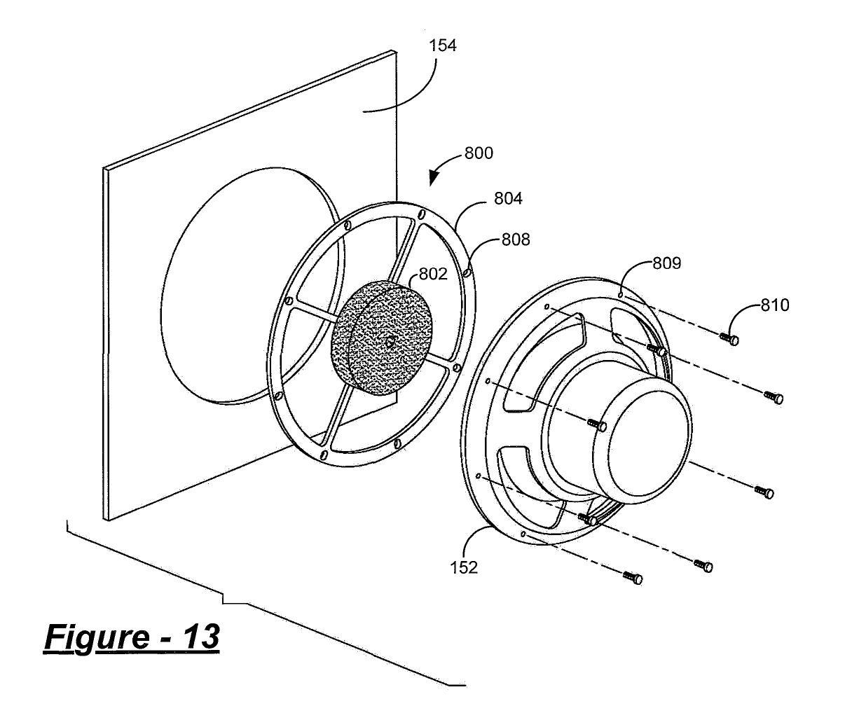

Turning now to FIGS. 10-14, a speaker attenuation apparatus 800 according to the present teachings may include an attenuating member 802 and a mounting bracket 804. As shown in FIGS. 12-14, mounting bracket 804 may be positioned between speaker 152 and baffle board 154 of speaker cabinet 150, with attenuating member 802 being concentrically attached to mounting bracket 804. In this way, attenuating member 802 may also be concentrically positioned with respect to speaker 152.

With reference to FIGS. 10-11, attenuating member 802 may include one or more layers of foam, also known as acoustic foam. The foam may be either open cell foam or closed cell foam, although open cell foam may be preferred over closed cell foam in improving evenness of tone of the speaker and reducing “beaminess” of the speaker without creating a “hole in the sound.”

Attenuating member 802 may, for example, be one inch thick, although other suitable thicknesses may likewise be appropriately used. Attenuating member 802 may be attached to mounting bracket 804 with glue, gum, Velcro, screws, rivets, and/or any suitable fastener.

Mounting bracket 804 may include spokes 806 extending from a circumferential edge of mounting bracket 804 and connecting at a center of mounting bracket 804. As shown, mounting bracket may include four spokes 806. Any suitable number of spokes, however, may be used. For example, mounting bracket may include as few as one spoke and as many as eight spokes or more. Mounting bracket 804 may be made of plastic, rubber, and/or any suitable material for mounting and attaching in accordance with the present teachings.

Attenuating member 802 may be attached to mounting bracket 804 at the center of mounting bracket 804. Attenuating member 802 may also be attached to any one and/or all of the spokes 806.

With reference to FIGS. 12-14, speaker attenuation apparatus 800, including mounting bracket 804 with attached attenuating member 802, may be installed on or in guitar speaker cabinet 150 between speaker 152 and baffle board 154. Mounting bracket 804 may include one or more mounting holes 808. Similarly, speaker 152 may include one or more mounting holes 809 for attaching speaker 152 to baffle board 154 of speaker cabinet 150 with one or more mounting screws 810. Mounting screws 810 may be received by corresponding screw receiving holes in baffle board 154.

For ease of installation, the one or more mounting holes 808 of mounting bracket 804 may align with the one or more mounting holes 809 of speaker 152. In this way, both the speaker 152 and the mounting bracket 804 may be attached to baffle board 154 with the same one or more mounting screws 810. Mounting bracket 804 may include multiple sets of mounting holes 808 to match different speaker mounting hole configurations for different speakers.

Although mounting bracket 804 is shown positioned between baffle board 154 and speaker 152, mounting bracket 804 may alternatively be positioned on the opposite side of the baffle board 154 as speaker 152. Further, although mounting bracket 804 is shown mounted to baffle board 154 with the same one or more mounting screws 810 used to mount speaker 152 to baffle board, mounting bracket 804 may be alternatively mounted to baffle board 154 with a different set of one or more mounting screws.

With reference to FIG. 12, mounting bracket 804 is shown installed within housing 156 of guitar speaker cabinet 150, attached to baffle board 154, and positioned between speaker 152 and baffle board 154, as viewed from outside speaker cabinet 150.

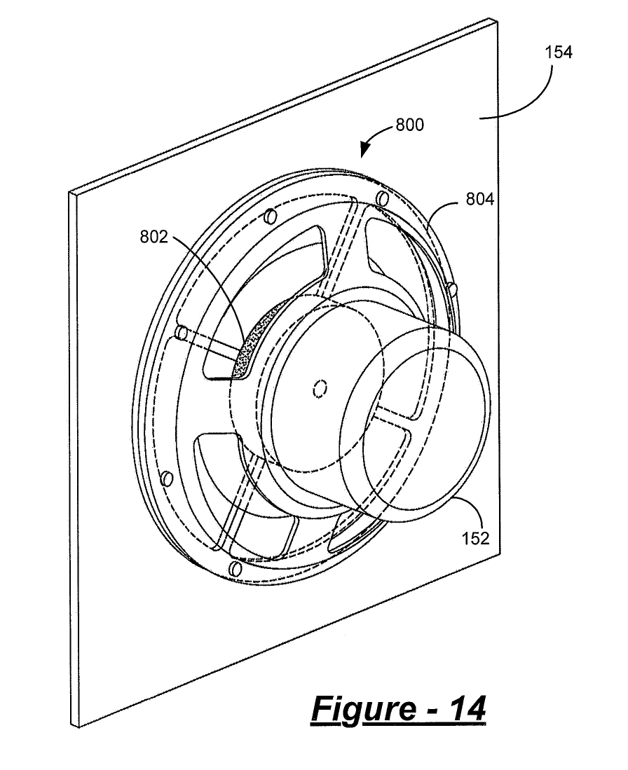

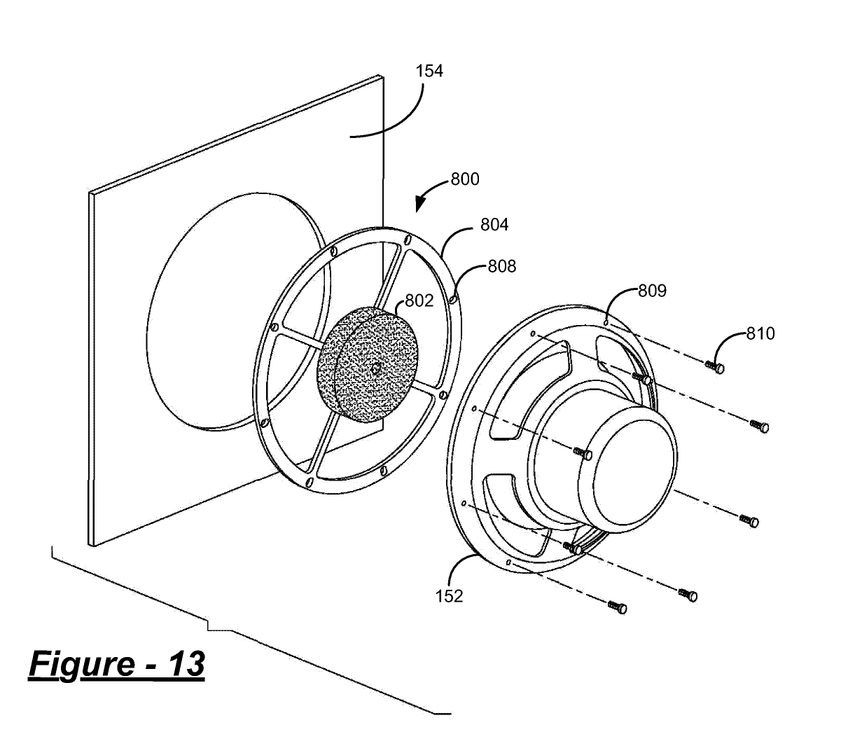

With reference to FIG. 14, mounting bracket 804 is shown attached to baffle board 154, and positioned between speaker 152 and baffle board 154, as viewed from the speaker side of the baffle board 154, i.e., from within speaker cabinet 150.

By using existing hardware, i.e., existing mounting screws 810, the speaker 152, and the baffle board 154, speaker attenuation apparatus 800 may be easily adapted for use with existing speaker cabinets 150. In this way, a user may easily install speaker attenuation apparatus 800 on an existing speaker cabinet 150 without modification of the existing speaker 152 or speaker cabinet 150. Likewise, a user may easily uninstall speaker attenuation apparatus 800 and return the existing speaker cabinet 150 to its original configuration without modification of the existing speaker 152 or speaker cabinet 150.

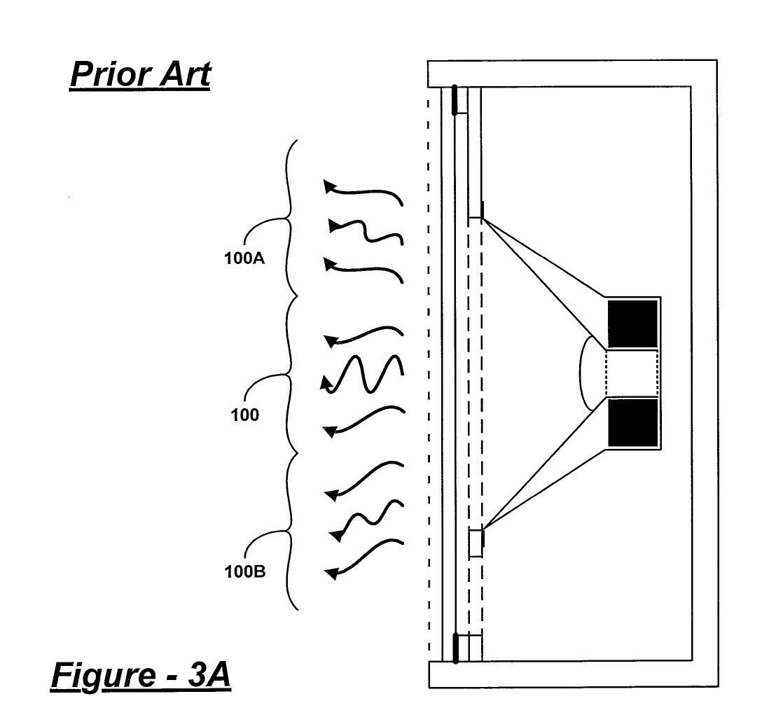

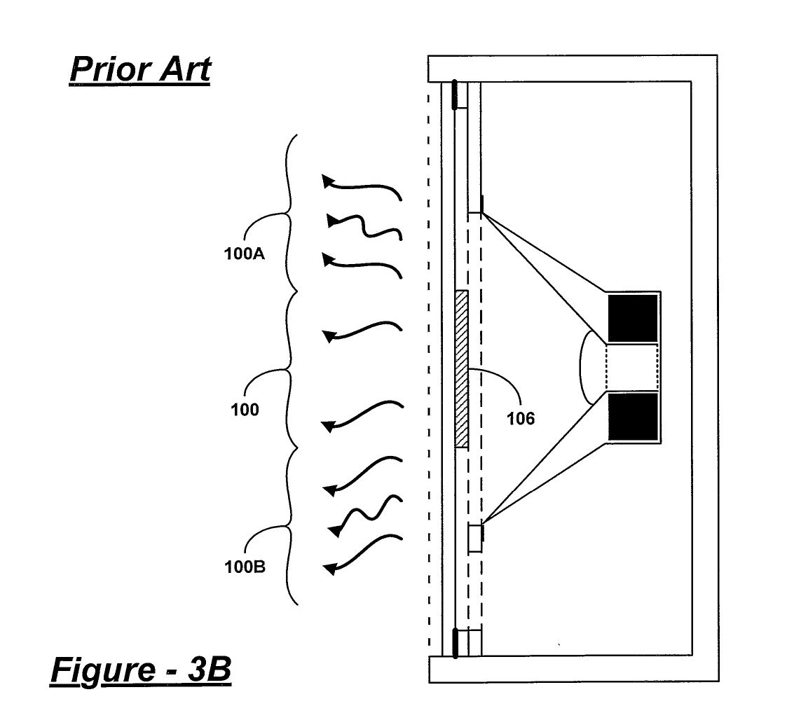

In this way, speaker attenuation apparatus 800 may be easily installed to improve evenness of the speaker tone in a manner and to a degree that is readily perceptible. By positioning attenuating member 802, attached to mounting bracket 804, concentrically with speaker 152, the amplitude of higher frequencies in the central beam region 100 (as shown in FIG. 3A) may be reduced without creating a “hole in the sound.” The higher frequency amplitudes may more closely match the amplitudes of the lower frequencies in the central beam region 100. Moreover, the amplitudes of the lower frequencies in the central beam region 100 may not be adversely affected. Accordingly, the amplitudes of higher frequencies in the central beam region 100 may be similar to those of higher frequencies in the outer beam regions 100A and 100B without causing a dramatic mismatch in amplitudes of lower frequencies in the central and outer beam regions. In other words, the “beaminess” of the speaker is effectively reduced without creating a “hole in the sound” in the central beam region 100. As a result, audiences in large venues will be treated to a pleasing tone even when the sound technician places the microphone to the local PA system in the central beam region of the speaker. Moreover, audience members proximate to the speaker in the central beam region will also experience the pleasing tone, and not the “ice pick highs” or “sizzle” of an unattenuated speaker, or the “muddy” tone of a blocked speaker.

What is claimed is:

1. A speaker attenuation system comprising a foam attenuating member attached to a mounting bracket, said mounting bracket being configured for attachment to a baffle board of a speaker cabinet and said foam attenuating member configured to be positioned in a central beam region of a speaker of said speaker cabinet when said mounting bracket is attached to said baffle board.

2. The speaker attenuation system of claim 1, said mounting bracket being positioned between said speaker and said baffle board when said mounting bracket is attached to said baffle board.

3. The speaker attenuation system of claim 1, said foam attenuating member being disc shaped and positioned concentrically with said speaker of said speaker cabinet when said mounting bracket is attached to said baffle board.

4. The speaker attenuation system of claim 1, said mounting bracket having a plurality of bracket mounting holes, each bracket mounting hole being aligned with a corresponding speaker mounting hole of said speaker.

5. The speaker attenuation system of claim 1, said mounting bracket having at least one spoke extending from a circumferential edge of said mounting bracket to a center of said mounting bracket.

6. The speaker attenuation system of claim 1, said mounting bracket having a plurality of spokes extending from a circumferential edge of said mounting bracket and meeting at a center of said mounting bracket.

7. The speaker attenuation system of claim 6, said foam attenuating member being attached to said center of said mounting bracket.

8. The speaker attenuation system of claim 6, said foam attenuating member being attached to at least one spoke of said plurality of spokes.

9. The speaker attenuation system of claim 1, said foam attenuating member being four to eight inches in diameter and one to three inches thick.

10. The speaker attenuation system of claim 1, said foam attenuating member including an open cell foam material.

11. The speaker attenuation system of claim 1, said foam attenuating member including a closed cell foam material.

12. A speaker cabinet comprising:
a baffle board;
a speaker attached to said baffle board;
a foam attenuating member attached to a mounting bracket, said mounting bracket being attached to said baffle board and said foam attenuating member being positioned in a central beam region of said speaker.

13. The speaker cabinet of claim 12, said mounting bracket being positioned between said speaker and said baffle board.

14. The speaker cabinet of claim 12, said foam attenuating member being disc shaped and positioned concentrically with said speaker.

15. The speaker cabinet of claim 12, said mounting bracket having a plurality of bracket mounting holes, each bracket mounting hole of said plurality being aligned with a corresponding speaker mounting hole of said speaker.

16. The speaker cabinet of claim 12, said mounting bracket having a plurality of spokes extending from a circumferential edge of said mounting bracket and meeting at a center of said mounting bracket.

17. The speaker cabinet of claim 12, said foam attenuating member including an open cell foam material.

18. The speaker cabinet of claim 12, said foam attenuating member including a closed cell foam material.

19. A speaker attenuation method, comprising mounting a bracket to a baffle board of a speaker cabinet, said bracket having a foam attenuating member attached thereto, said foam attenuating member being positioned in a central beam region of said speaker when said bracket is mounted to said baffle board.

20. The speaker attenuation method of claim 19, said mounting said bracket comprising positioning said bracket between said speaker and said baffle board.

21. The speaker attenuation method of claim 19, said mounting said bracket comprising aligning at least one mounting hole of said mounting bracket with at least one mounting hole of said speaker and attaching said mounting bracket and said speaker to said baffle board with at least one screw, said at least one screw being received by said at least one mounting hole on said mounting bracket and said at least one mounting hole on said speaker.

22. The speaker attenuation method of claim 19, said foam attenuating member including an open cell foam material.

23. The speaker attenuation method of claim 19, said foam attenuating member including a closed cell foam material.
